(19) United States
(12) Patent Application Publication
(10) Pub. No.: US 2013/0109189 A1
(43) Pub. Date: May 2, 2013

(54) SYSTEM ARCHITECTURE FOR PLASMA PROCESSING SOLAR WAFERS

(71) Applicant: Intevac, Inc., Santa Clara, CA (US)

(72) Inventors: Young Kyu Cho, San Jose, CA (US); Karthik Janakiraman, San Jose, CA (US); Terry Bluck, Santa Clara, CA (US); Diwakar Kedlaya, San Jose, CA (US)

(73) Assignee: INTEVAC, INC., Santa Clara, CA (US)

(21) Appl. No.: 13/666,869

(22) Filed: Nov. 1, 2012

Related U.S. Application Data
(60) Provisional application No. 61/554,453, filed on Nov. 1, 2011.

(51) Int. Cl. H01L 21/3065

(52) U.S. Cl. 438/710; 156/345.51; 156/345.53; 156/345.31; 257/E21.218

(57) ABSTRACT

A system for plasma processing of wafers at high throughput, particularly suitable for processing solar cells. A loading station has a loading conveyor, a loading transport mechanism, and a chuck loading station accepting transportable electrostatic chucks, wherein the loading transport mechanism is configured to remove wafers from the conveyor and place them on the transportable electrostatic chucks. The transportable chuck is delivered to at least one processing chamber to perform plasma processing of wafers. An unloading station has an unloading conveyor, an unloading transport mechanism, and a chuck unloading station accepting the transportable electrostatic chucks from the processing chamber, wherein the unloading transport mechanism is configured to remove wafers from the transportable electrostatic chucks and place them on the conveyor. A chuck return module configured for transporting the transportable electrostatic chucks from the chuck unloading station to the chuck loading station.

### RELATED APPLICATION

This application claims priority benefit from U.S. Provisional Application Ser. No. 61/554,453, filed on Nov. 1, 2011, the content of which is incorporated herein by reference in its entirety.

### BACKGROUND

1. Field

This disclosure relates to systems for processing of solar cells and, in particular, to system architecture for plasma processing of solar cells, such as plasma etching of solar cells.

2. Related Art

Processing chambers, such as plasma chambers, used to fabricate solar cells have the same basic elements of processing chambers used for fabricating integrated circuits (IC), but have different engineering and economic requirements. For example, while chambers used to fabricate integrated circuits have throughput on the order of a few tens of wafers per hour, chambers used for fabricating solar are required to have throughput on the order of a few thousands of wafers per hour. On the other hand, the cost of purchasing and operating a solar cell processing system must be very low.

Recently there has been rapid growth of activity to fabricate photo-voltaic (PV) cells from silicon wafers, the same basic material used in the fabrication of integrated circuits. One of the fabrication steps in the manufacture of PV cells is roughening the surface of the cell to reduce the number of photons that escape from the cell, to thereby increase the efficiency of the cell. This process step is generally performed through use of “wet chemistry,” that is, placing the cell in a chemical bath that etches away a thin layer of silicon in a non-uniform manner thereby roughening the surface. This technique, although inexpensive, is imprecise and does not fully achieve the desired result, especially in polysilicon wafers wherein different grains may have different crystalline orientation. Performing this function using semiconductor plasma etch methods can provide improved results to further increase the cell efficiency.

Reactive Gas Etch systems are in widespread use in the integrated circuit industry. These systems are used for selective removal of materials from silicon wafers and are generally configured as a cluster tool. Such systems facilitate taking wafers one at a time from a cassette, placing wafers individually in chambers of the cluster tool, etching the wafers individually, one at a time in each of the process chambers, performing other process steps if required, and returning the wafer to the cassette. The Cassette is then removed from the cluster tool and anther cassette enters the tool.

Unfortunately, using semiconductor techniques for fabrication of solar cells is economically prohibitive. High cost and low throughput is acceptable in the IC fabrication since a processed semiconductor wafer is worth approximately 1,000 times the value of a processed PV cell. Therefore, while semiconductor tools operate at around 100 wafers per hour, PV lines must run at several thousand cells per hour. To reduce silicon cost, PV wafers are much thinner than semiconductor wafers and, consequently, very fragile. While the breakage of a semiconductor wafer is a rare event and typically causes the tool to be shut down, in PV production cell breakage is routine and the line must keep operating. Thus, the requirements for a PV plasma processing systems, such as dry etch, are very different from that for semiconductor etch.

Various other steps involved in the fabrication of solar cells require exposure of the wafer to plasma, such as plasma enhanced chemical vapor deposition (PECVD), physical vapor deposition (PVD), etc. The requirements on all plasma processing on solar cells are similar, in that the throughput needs to be on the order of several thousand wafers an hour, the system and its operational cost should be low, and wafer breakage should not require a system shut-down.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

This disclosure provides an architecture for plasma processing of PV cells, which achieves a high level of process control, very high throughput, at very low cost. This has been done by using semiconductor plasma techniques, but in a different configuration and completely different system architecture.

Various embodiments provide an architecture in which electrostatic chucks are moved through the system carrying wafers. After the wafers completed processing, the wafers are removed from the chucks and the chucks are recycled through the system. The system includes sufficient number of chucks such that the processing chambers are always occupied and always process wafers. Also, the system uses conveyors to deliver and remove wafers from the system, so that several rows of wafers can be transported and processed simultaneously.

According to one embodiment, a plasma processing system is disclosed, comprising: a loading station having a loading conveyor, a loading transport mechanism, and a chuck loading station accepting transportable electrostatic chucks, wherein the loading transport mechanism is configured to remove wafers from the conveyor and place them on the transportable electrostatic chucks; at least one processing chamber coupled to the loading station and configured for receiving the transportable electrostatic chucks from the loading station and perform plasma processing of wafers positioned on the transportable electrostatic chucks; an unloading station having an unloading conveyor, an unloading transport mechanism, and a chuck unloading station accepting the transportable electrostatic chucks from the processing chamber, wherein the unloading transport mechanism is configured to remove wafers from the transportable electrostatic chucks and place them on the conveyor; and, a chuck return module configured for transporting the transportable electrostatic chucks from the chuck unloading station to the chuck loading station.

Also disclosed is a method for plasma processing of wafers, comprising: delivering wafers into an evacuated loading station; inside the evacuated loading station, loading the wafers onto transportable electrostatic chucks; transporting the electrostatic chuck into a plasma processing chamber; igniting and sustaining plasma inside the processing chambers to thereby process the wafers; transporting the electrostatic chuck into an unloading station; removing the wafers from the electrostatic chuck; and, returning the chuck to the evacuated loading station.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A illustrates an example of a system having one plasma chamber for processing substrates, according to an embodiment of the invention.

FIG. 1B illustrates an example of a system having multiple plasma chambers for processing substrates, according to an embodiment of the invention.

FIG. 2 is a general schematic illustrating the architecture of a system according to embodiment of the invention.

FIG. 3 is a flow chart illustrating a process according to an embodiment of the invention.

FIG. 4A is a schematic illustrating the major parts of an electrostatic chuck according to one embodiment, while FIGS. 4B and 4C illustrate two different embodiments for a partial cross-section along line A-A of FIG. 4A.

FIG. 5 is a schematic illustrating the major parts of an electrostatic chuck and carrier according to one embodiment of the invention.

FIG. 6 is a flow chart illustrating a process flow for fabricating solar cells, according to embodiment of the invention.

### DETAILED DESCRIPTION

Various features of the plasma processing system according to embodiments of the invention will now be described with reference to the drawings. The description will include examples of a system having a single plasma chamber and system having several plasma processing chambers. The disclosed embodiments are particularly suitable for fabrication of solar cells at high throughput.

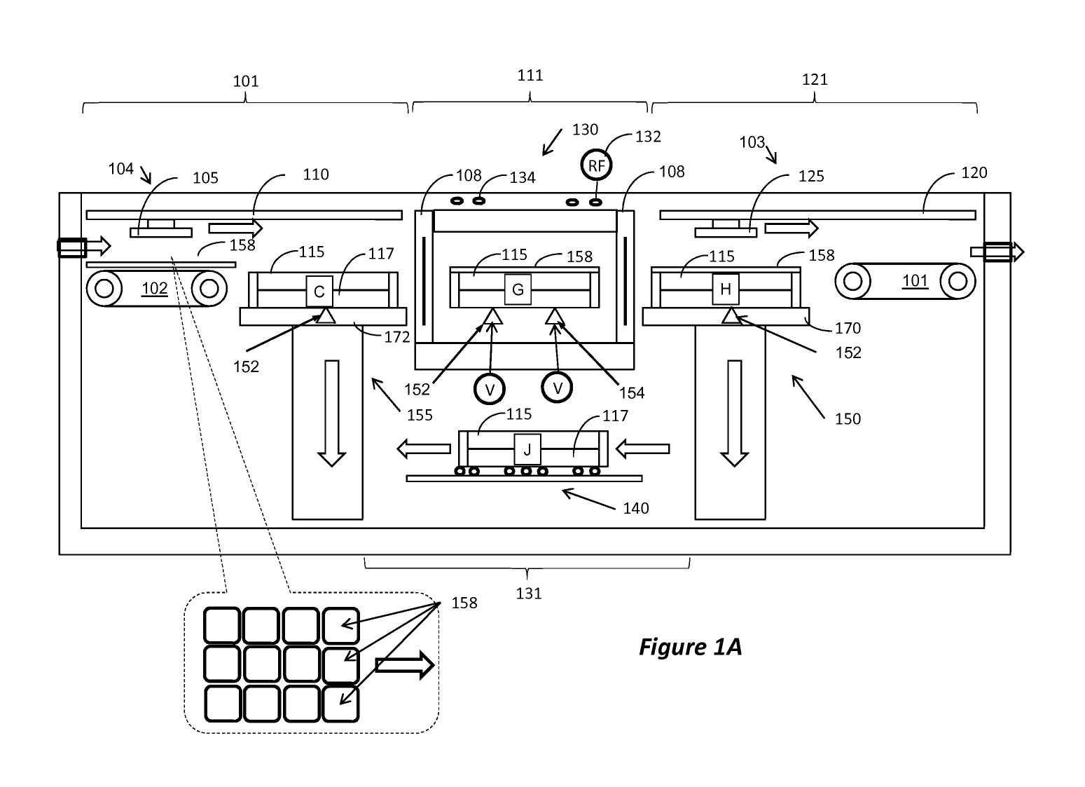

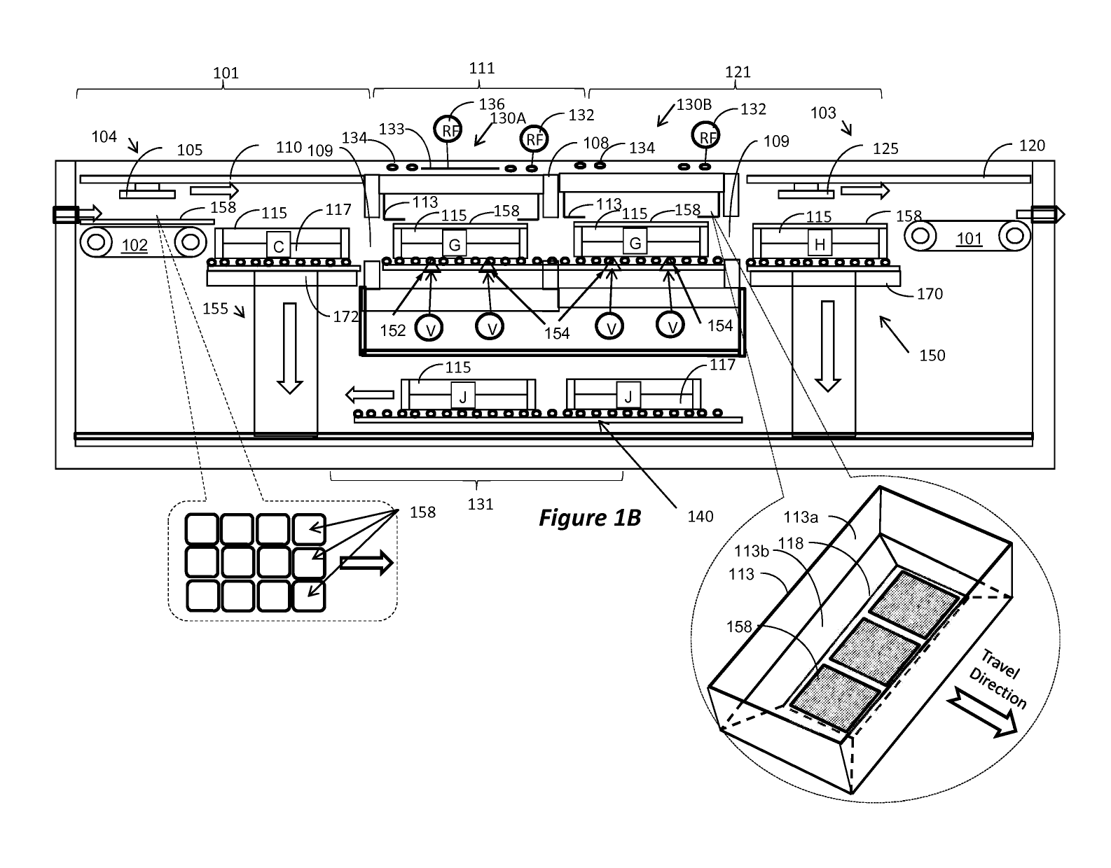

FIG. 1A illustrates an embodiment having a single plasma processing chamber 130. Such a system can be used, for example, for plasma processing of solar cells, such as for texture etch of silicon wafers which are fabricated into solar cells. The architecture of this embodiment enables a very high throughput at low system and operational cost. In this example, the plasma chamber 130 is configured for processing several wafers simultaneously. For example, in FIG. 1A the wafers 158 are transported and processed in three rows, as shown in the callout. Thus, the chamber 130 can be configured to process three wafers simultaneously (an array of 3×1), six wafers (an array of 3×2), nine wafers (an array of 3×3), etc. Of course, the system can be designed to transport and process a different number of rows, e.g., two rows, four rows, etc., or even a single row.

The system illustrated in FIG. 1A includes a loading module 101, a processing module 111, an unloading module 121, and a chuck return module 131. The loading module 101 delivers fresh wafers to the system and loads them onto chucks. The loading module 101 includes a conveyor 102, a loading transport mechanism 104, and chuck-carrier elevator 155, which forms station C in its up position. Conveyor 102 continuously delivers wafers, here in three rows, as shown in the callout. The loading transport mechanism 104 removes wafers from the conveyor 102 and loads them onto chucks 115, which are attached to carriers 117 positioned on elevator 155 in station C. The chuck elevator accepts carriers 117 from carrier return module 140 and raises them to station C to be loaded again with wafers.

In this example, each wafer is loaded onto an individual chuck 115. Notably, unlike conventional systems, in this embodiment transportable electrostatic chucks are used. Rather than loading wafers onto a chuck fixed inside the processing chamber, the chucks are first loaded with wafers and are then transported by carriers 117 into the processing chamber 130 for processing. In this example, each carrier 117 supports three chucks 115. This enables higher throughput as there are always chucks loaded with wafers and ready to be transported into the chamber for processing.

The processing module 111 comprises one or more processing chambers 130. In this embodiment, a single plasma processing chamber 130 is shown. Chamber 130 is illustrated as inductively-couple plasma chamber having RF source 132 and antenna 134, but other processing chambers may be used. In this example, the chamber is configured to accept three electrostatic chucks 115, which are attached to and transported on one carrier 117. Inside chamber 130 power is coupled to the chucks for chucking and for wafer biasing via contacts 152 and 154. The processing environment of chamber 130 is isolated from the rest of the system via shutters 108.

The unloading module 121 includes chucks elevator 150, which receives the carrier 117 supporting the chucks 115 from the processing chamber 130 after processing has been completed and, once the wafers 158 are removed from the chucks 115, transfers the carrier with the chucks to the chucks return module 131. The wafers 158 are removed from the chucks by unloading transport mechanism 103 and placed onto the unloading conveyor 101 to be removed from the system.

The chuck return module 131 basically consists of transporting mechanism 140 to shuttle chucks from the unloading elevator 150 to the loading elevator 155. In this example, the transporting mechanism 140 is within vacuum environment of the system and is positioned under the processing chamber 130.

FIG. 1B illustrates an embodiment wherein multiple processing chambers are positioned serially. The elements on FIG. 1B that are similar to those in FIG. 1A are identified with the same reference numbers. The system of FIG. 1B may be designed the same as that of FIG. 1A, except with multiple processing chambers. However, to highlight other variations, the system illustrated in FIG. 1B includes various elements using a different design from that of FIG. 1A. These will be explained further below.

As can be seen, the general architecture of the systems of FIGS. 1A and 1B is very similar, except that in this embodiment two plasma processing chambers, 130A and 130B are positioned serially. Of course, more than two chambers may be arrange in a similar way, but for purpose of illustration only two are shown. The system operates as in FIG. 1A, except that when processing is completed in Chamber 130A, the chucks are transported to chamber 130B for processing. From chamber 130B the chucks are removed onto elevator 150, just like in FIG. 1A. Also, since the chuck transport module is now longer, it can accommodate several chucks serially, although this is optional and not necessary.

Another feature illustrated in FIG. 1B is the inclusion of a hybrid capacitive-inductive RF source in chamber 130A. The same source can be used in chamber 130B, but for purpose of illustrating the difference chamber 130B remains the same as chamber 130 in FIG. 1A. In chamber 130A plasma is sustained using antenna 134 and RF power source 132 as was shown with chamber 130 in FIG. 1A. However, in addition, capacitive coupling of RF power is also employed. Specifically, electrode 133 is provided in the ceiling of chamber 130B. RF power from source 136 is coupled to the electrode 133. A counter electrode is provided in the chucks. Thus, in chamber 130A RF power is coupled to the plasma both inductively and capacitively.

FIG. 1B illustrates another feature that provides better plasma control and increase in transport speed and system reliability. Specifically, each processing chamber 130A and 130B is provided with plasma shield 113. The plasma shield 113 confines the plasma to only the area above the wafers and within the shield. The remaining interior of the chamber is free of plasma. An example of shield 113 is illustrated in the callout, showing a top-interior view of the shield. As shown, the shield generally has sidewalls 113a and bottom plate 113b. The bottom plate 113b has a cutout 118, exposing the plasma to the processed wafers 158—here three wafers simultaneously.

As a consequence of including the plasma shield 113, there's no more need for shutters 108 at the entrance and exit of the chamber. Instead, simple windows 109 are provided that are constantly open during transport and processing (having no valve or shutter) to thereby enable free transport of the carriers into and out of the chamber. The carriers enter the chamber at a level such that the shield is just over, but not touching the chuck. In one embodiment the bottom plate 113b of the shield is one or a few millimeters, e.g., 1-5 mm, above the wafers 158.

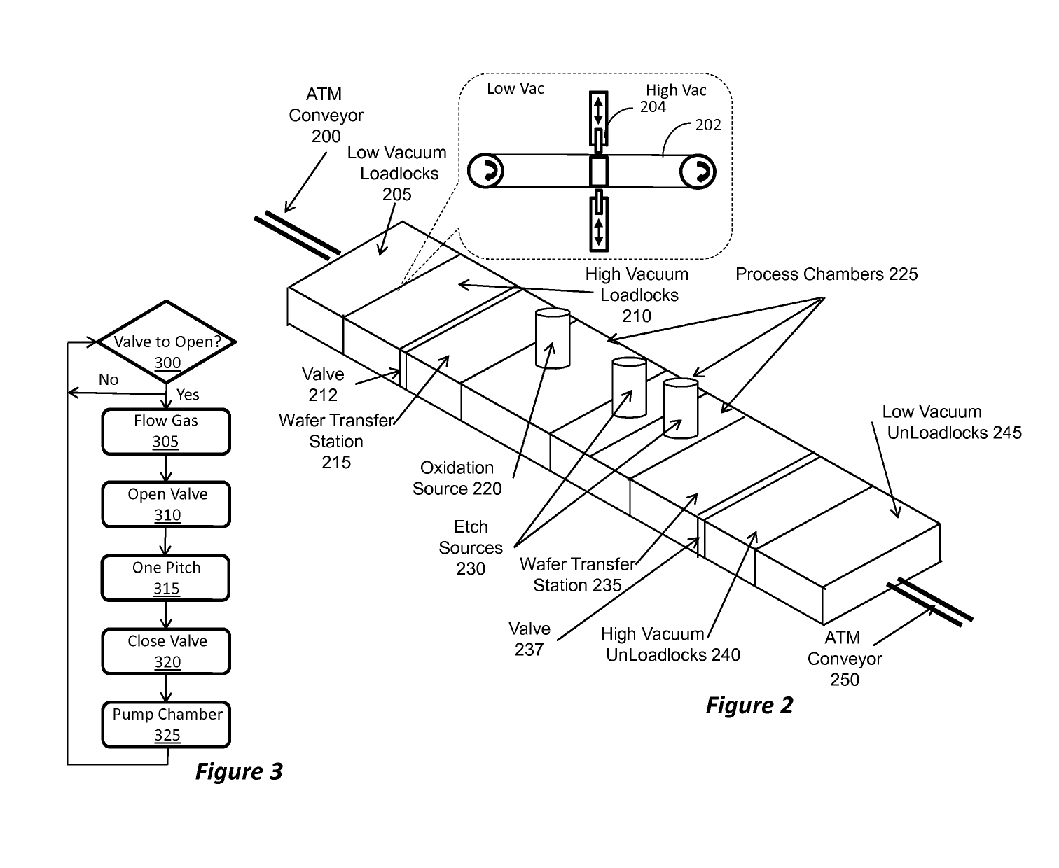

The following is an example of a processes sequence using the embodiment of FIGS. 1A or 1B. The wafers 158 are delivered to the system on an incoming conveyor 102. The wafers arrive onto conveyor 102 after passing low vacuum load lock and high vacuum load lock, which will be described later with reference to FIG. 2. In this example, several wafers 158 are arranged abreast in the direction orthogonal to the conveyor's travel direction. For example, three wafers 158 can be arranged in parallel, as shown in the callout, which is a top view of the substrates on the conveyor, with the arrow showing the direction of travel.

The wafer transport mechanism 104 is used to transport the wafers 158 from the conveyor 102 onto the processing chucks 115. In this example, the transport mechanism 104 employs an electrostatic pickup chuck 105, which is movable along tracks 110 and uses electrostatic force to pick up one or more wafers, e.g., one row of three wafers, and transfer the wafers to the processing chucks 115. In this example, three processing chucks 115 are used to receive the three substrates held by the pickup chuck 105. As shown in FIG. 1, the loading of wafers onto the processing chuck 115 is done at the loading station C, having elevator 155 which holds the carrier 117 with the three chucks 115. The carrier 117 with the processing chucks 115 are then transported into the first processing chamber 130 (via shutter 108 if using the embodiment of FIG. 1A).

In the example of FIG. 1A the process chamber 130 is isolated from the loading station and other chambers by shutter 108. Shutter 108 greatly reduce conductance to adjacent chambers, allowing for individual pressure and gas control within the process chambers without vacuum valves and o-ring seals. On the other hand, as shown in FIG. 1B, the chambers can be fitted with plasma shields 113, which obviate the need for the shutters.

Once the carrier 117 with chucks 115 are positioned inside the processing chamber 130, electrical contact is made to the chucks 115 by contacts 152 and 154, to deliver the required voltage potential. Plasma processing then commences and the substrates are processed in their stationary position. That is, in this embodiment, once the carrier reaches its proper position inside the chamber, motion of the carrier is stopped for the entire duration of the plasma processing, which may be a few seconds, up to a few tens of seconds. Once processing is completed, motion of the carrier is commences again and it is transported to the next station in the sequence. When processing is completed at the last chamber in the series of chambers, the carrier 117 with the chucks 115 is transported to the unloading station 150.

At the unloading station 150, the wafer transport mechanism 103 is used to unload wafers from the chucks 115 and transport the wafers onto unload conveyor 101. Transport mechanism 103 employs an electrostatic wafer pickup head 125, which rides on tracks 120, similar to the pickup chuck 105. The pickup head 125 uses electrostatic forces to transfers wafer from process chucks 115 to outgoing conveyor 101. Outgoing wafer conveyor 101 receives the wafers from the pickup head 125 and conveys them to further processing downstream.

The carrier 117 with the chucks 115 is then lowered by elevator 150 and is transported by the return module 131 to elevator 155, which returns the carrier to position C for receiving another batch of wafers. As can be understood, several carriers with processing chucks are used, such that each station is loaded and the processing chamber is always occupied and processing wafers. That is, as carrier with one group of chucks leaves the processing chamber into station H, another carrier from station C is moved into the chamber and a carrier from elevator 155 is moved into station C. Also, in this embodiment, as the elevators 150 and 155 move carriers between process level and return level, they actively cool the process chuck 115 using, e.g., heat sinks 170 and 172. Alternatively, or in addition, cooling stations J are provided in the return module 140 to cool the chucks. The process chucks 115 are returned from unload station H to load station C via a return tunnel 140, which is positioned under the process level.

Electrical contacts 152 to the chuck are located on each elevator and in each process chamber for electrostatic chucking of wafers. That is, since the chucks are movable, no permanent connections can be made to the chucks. Therefore, in this embodiment, stations C and H and each processing chamber 130 include electrical contacts 152 to transfer electrical potential to the chuck and enable electrostatic chucking Optionally, DC bias contacts 154 are also located in each process chamber 130 for DC bias of wafer if required. That is, for some processing, DC bias is used in addition to plasma RF power, in order to control the ion bombardment from the plasma on the wafer. The DC potential is coupled to the wafers by DC bias delivered from contacts 154. Alternatively, biasing of the wafers is done by capacitive coupling to the chucks and without any direct contact of a conductor to the wafers.

Thus, as seen from the above, the systems illustrated in FIGS. 1A and 1B may utilize several process chucks 115, which continuously move from load position, through a series of process chambers 130, to an unload position. The process chambers 130 may be individually pumped and separated from each other and from the load and unload zones by shutters 108, or may include plasma shields. Either design allows for individualized gas species and pressure control in each plasma processing zone.

In the examples of FIGS. 1A and 1B, several chucks 215 are present in each process chamber during processing, so that multiple substrates are being plasma processed simultaneously. In this embodiment, the wafers are processed simultaneously by being supported on several individual chucks, e.g., three chucks, situated abreast and attached to a carrier 117. In one specific example, each chamber is fabricated to hold one row of three individual chucks on a carrier, so as to simultaneously process three wafers. Of course, other arrangement may be used, e.g., a two by three array of chucks, etc.

FIG. 2 illustrate an example of an architecture that includes an atmospheric conveyor 200 for loading wafers into low vacuum load lock 205. That is, the wafers are transferred from conveyor 200 onto another conveyor positioned inside the low vacuum load lock 205 by jumping a small gap between the conveyors, where a slit with a vacuum valve (not shown) is positioned on the sidewall of the vacuum chamber to enable wafer passage into the low vacuum environment. The wafers are then transferred to a high vacuum load lock 210 by passing through a valve on the wall separating the low vacuum and high vacuum load locks, as illustrated in the callout. In this embodiment, a valve 204 is provided, which closes on the conveyor belt 202 when the belt is not in motion, so as to support vacuum inside the high vacuum load lock. That is, the conveyor belt 202 is made of thin but strong material, such as Mylar. It is threaded through a narrow slit between the low vacuum load lock 205 and high vacuum load lock 210. The conveyor belt 202 is energized intermittently rather than continuously, wherein during each energized state it transports one column of wafers, referred to as “one pitch.” When the conveyor belt 202 stops its motion, the valve 204 closes and presses on the conveyor belt 202, to thereby separate the environment inside the high vacuum load lock 210 from that of low vacuum load lock 205. Such an arrangement minimizes the gaps that the wafers have to traverse so as to minimize breakage.

The conveyor 202 delivers the wafers to a wafer transfer station 215, such as loading module 101 illustrated in FIGS. 1A and 1B. As explained with reference to FIGS. 1A and 1B, in wafer transfer station 215 the wafers are loaded onto electrostatic chucks which are transportable on carriers. The chucks are then transported by the carriers into a first processing chamber 225, here shown as an oxidation chamber having oxidation source 220. Thereafter, the carriers with the chucks are moved through successive processing chambers 225, here two etching chambers having plasma sources 230. The carriers then exit the processing chambers and move to unloading station 235, where the substrates are removed from the chucks and transferred to conveyor within high vacuum chamber 240. The wafers are then transferred to the low vacuum chamber 245, and then are transferred to an atmospheric conveyor 250. The carriers with the empty chucks are then returned to the transfer station 215 to be reloaded with wafers.

With the architecture illustrated in FIGS. 1A-2, the entry and exit load locks handle several, e.g., 3, substrates at a time, and no fixtures or carriers enter the machine with the substrates. This is achieved by transporting the substrates on a belt 200 in atmosphere, which ends very near a gate valve (not shown) to the entry load lock 205, wherein the gate valve motion is vertical. When the valve opens, the substrates “jump” the gap to a belt inside the load lock 205, whereupon the valve closes and vacuum is established inside load lock 205. During each one pitch operation, one column of wafers is delivered into the load lock 205.

After moving through the load lock chamber(s) the substrates are lifted from the belt by an electrostatic pickup, which then moves the substrates forward one pitch and the substrates are lowered onto substrate holders, e.g., electrostatic chucks. During each such operation, one column of wafers is loaded onto a corresponding column of chucks. The system contains multiple substrate holders (i.e., e-chucks transportable on carriers) that are not fixed in place, but rather are capable of being moved independently forward and backward. Additionally, at the end points of the processing chambers elevators are provided for lowering and raising the carriers with the chucks.

The transportable chucks are multi-function. They hold several (e.g., 3) substrates securely and in a precise position for simultaneous processing. In the embodiments illustrated, three chucks enter each processing chamber simultaneously, each holding one substrate. The chucks move the substrates from process station to process station, one pitch at a time. To enable rapid and accurate motion of the chucks, in one example the chucks are moved using linear motors. The chucks also conduct heat away from the substrates to thereby maintain the temperature of the processed substrates at an acceptable level. To periodically remove the heat form the chucks, heat sinks are provided in the elevators or the chuck return module.

Another feature of the embodiment of FIG. 2 relates to the operation of the high vacuum load lock 210 and valve 212. Specifically, when the system of FIG. 2 is implemented using the arrangement shown in FIG. 1B, wherein the chamber attached to the transfer station 215 is provided with plasma shield and has no valve separating it from the transfer station, the operation of transferring wafers into the transfer station proceeds as shown in the flow chart of FIG. 3. In step 300 a system controller determines whether the valve 212 should be opened. If so, at step 305 the processor issues a signal to pump gas into the high vacuum load lock chamber 210. This equalizes or brings the pressure inside the high vacuum load lock 210 closer to that inside the transfer station 215. That is, since no valve is provided between the transfer chamber 215 and processing chamber 220, the flow of processing gasses into processing chamber 220 elevates the pressure inside transfer station 215 above that of load lock 210. If the valve 212 is opened, it would cause a high flow of gasses from transfer station 215 into load lock 210. Pumping gas into the transfer station 210 beforehand avoids this problem. Since the high vacuum load lock is generally under high vacuum, a very small amount of gas flow is needed to elevate the pressure inside the chamber and can be achieve by a very short burst of gas such as argon, nitrogen, etc.

After the gas is injected into transfer station 210, in step 310 the valve 212 is opened and in step 315 the conveyor is energize to progress one pitch, i.e., to transfer one column of wafers into the transfer station 215. In step 320 valve 212 is closed and in step 325 the pump is energized to evacuate the transfer station 210.

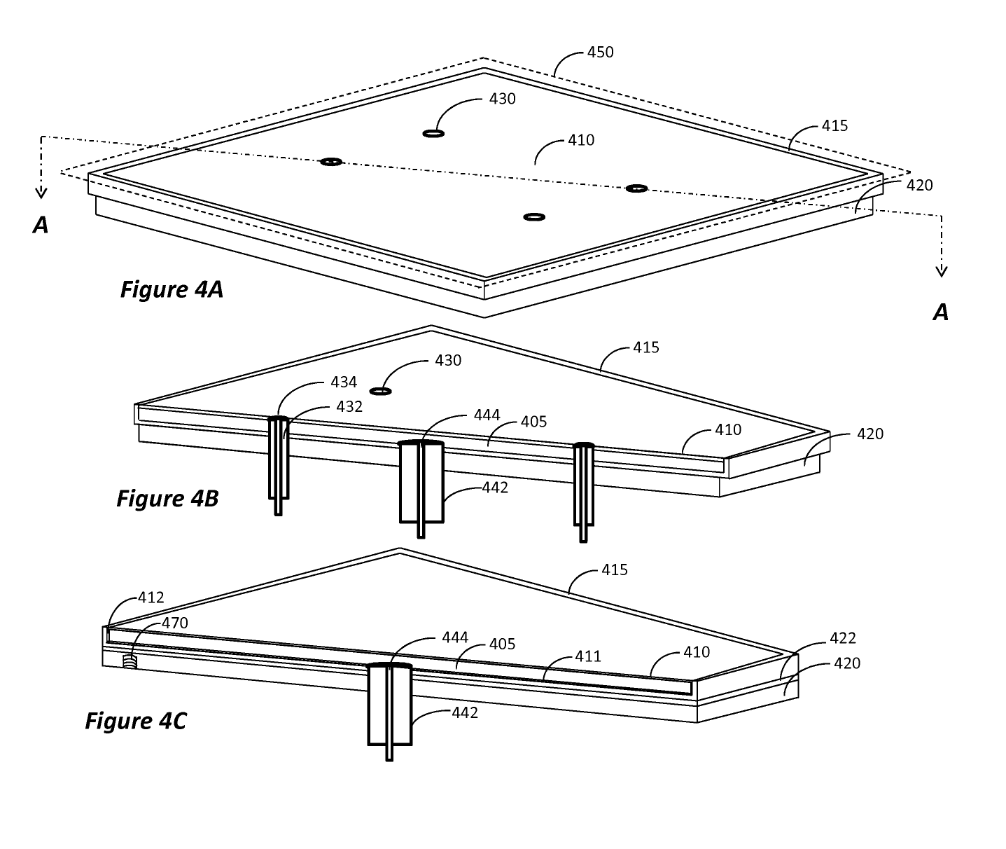

FIG. 4A is a schematic illustrating the major parts of an electrostatic chuck according to one embodiment, while FIGS. 4B and 4C illustrate two different embodiments for a partial cross-section along line A-A of FIG. 4A. The chucks body 405 is made of aluminum slab and is configured to have sufficient thermal mass to control heating of the chuck during plasma processing. The top surface of the body 405 is anodized, thereby forming electrically insulating anodized aluminum layer 410. The sides of the chuck are encased by ceramic layer or frame 415. Ceramic layer 415 may be a ceramic coating applied to all four sides of the aluminum body, e.g, using standard plasma spray coating or other conventional methods. In the embodiment shown in FIGS. 4A-4C, the aluminum body 405 is placed inside a ceramic “tub” such that all four sides and the bottom of the aluminum body 405 are covered by a ceramic frame 415. The body 405 is bonded to the ceramic frame 415. The top of the ceramic frame 415 is level with the top of the anodized aluminum layer 410. Also, the chuck is sized so that the chucked wafer extends beyond the ceramic sides 415, so as to cover the top of the ceramic sides 415. This is illustrated by the broken-line outline of wafer 150 in FIG. 4A.

The chuck is attached to a base 420, which may be made of an insulative or conductive material. An aperture is formed through the base 420 and an insulating sleeve 442 is positioned therein. A conductor contact rod 444 is passed through the insulating sleeve 442 so as to form electrical contact to the aluminum body 405. Conductor rod 444 is used to conduct high voltage potential to form the chucking force to chuck the wafers.

In some processing chambers it is necessary to bias the processed wafers so as to attract ions from the plasma towards the wafers. For such processing, the chuck is provided with contact points 430 to deliver voltage bias to the wafers. Each contact point 430 is formed by an insulating sleeve 432, which passes through the base 420 and though the body 405. A contact rod 434, which may be spring biased or retractable (not shown), passes through the insulating sleeve 432.

The protective ceramic frame 415 may be made of materials such as, e.g., alumina (aluminum oxide), SiC (silicon carbide), silicon nitride (Si₃N₄), etc. The selection of ceramic material depends on the gasses within the plasma and on potential contamination of the processed wafers.

The arrangement illustrated in FIGS. 4A and 4B provides certain advantages over prior art chucks. For example, due to its simple design, it is inexpensive to manufacture. Also, the anodized surface can endure repeated processing, while the ceramic frame protects the anodization and the chuck's body from plasma corrosion. Since the ceramic frame is designed to be slightly smaller than the chucked wafer, the ceramic frame is sealed by the chucked wafer, thereby preventing plasma attack on the edges of the chuck/ceramic frame.

The chuck of the embodiment illustrated in FIG. 4C is fabricated by machining an aluminum body 405. All the surfaces of the body 405 are then anodized, to provide a hard insulative surface, shown as top anodization layer 410, bottom anodization layer 411, and side anodization layer 412. The anodized aluminum body is bonded onto a ceramic tub 415 made out of, e.g., alumina, and serving as an insulator and protecting the sides of the anodized aluminum body from plasma corrosion. The ceramic tub is attached to, e.g., bonded onto, an insulating plate 422, made of, e.g., polyimide, Kapton®, etc. The thickness of the insulating plate 422 is determined depending on the dielectric constant of the plate's material, so as to provide the required capacitive coupling of RF power to the base plate 320. Base plate 420 is made of aluminum and is also anodized, and is used to capacitively couple RF from the plasma. The amount of coupling depends, in part, on the properties, such as thickness and dielectric constant, of the insulating plate 422. Also, alternatively, rather than using insulative plate, the bottom plate of tub 415 can be made thicker to provide the same insulating properties. Also, threaded holes 470 are provided to attach the chuck to a carrier, which is described below.

As noted above, the aluminum body 405 is anodized on all sides. Therefore, to make the electrical contact with contact rod 444, the anodization is removed from area of the contact on the bottom of the aluminum body. Additionally, the area where the anodization was removed is plated with a conductive layer such as, e.g., nickel, chromium, etc. When the contact rod 444 is inserted into the insulating sleeve 442, it contacts the plated conductive layer and good electrical contact is then maintained. No provisions are made for delivering bias power to the wafers. Instead, the bias potential is coupled capacitively without direct contact with the wafers.

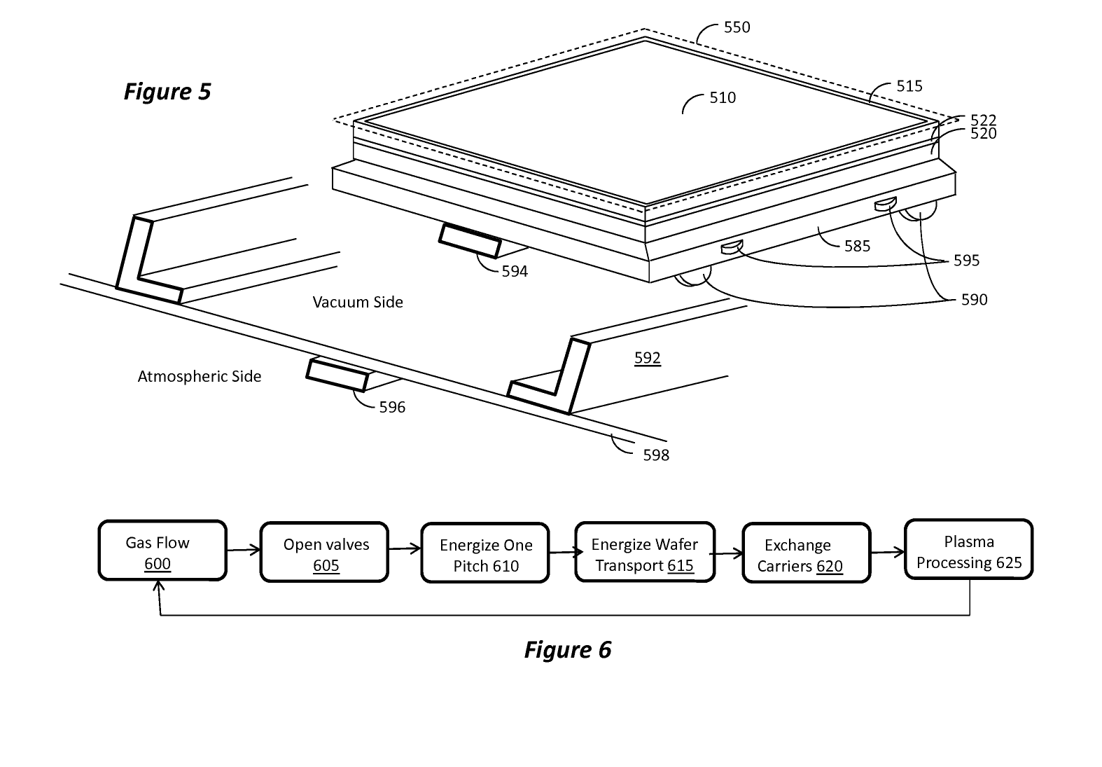

FIG. 5 illustrates an arrangement for utilizing the chucks described above in a plasma processing system, such as that illustrated in FIGS. 1A and 1B. Generally, the chuck is connected to a carrier 585, e.g., by bolting the base 520 to the carrier 585. The carrier 585 has one set of vertically-oriented wheels 590 and one set of horizontally oriented wheels 595, which are fitted to ride on rails 592. Rails 592 traverse both wafer transfer stations, all of the processing chambers, the elevators, and the chuck return module, as illustrated more clearly in FIGS. 1B. Note, however, that in FIG. 1B the rails are shown to have wheels. In such an embodiment the wheels are energized from outside the vacuum chamber and the carriers ride on the wheels. Conversely, in the embodiment of FIG. 5 the wheels are on the carriers themselves, and the rails have no wheels, just surfaces for the wheels to ride on.

In the embodiment of FIG. 5, motive force is provided by a linear motor which is partially positioned on the carrier in vacuum and partially positioned outside vacuum beyond the vacuum partition 598. For example, a series of permanent magnet 594 can be provided on the bottom of the carrier, while a series of coils 596 are positioned in atmospheric environment outside of partition wall 598. When coils 596 are energized, they generate magnetic force that traverses partition 598 and acts on the permanent magnets 594 so as to move the carrier.

FIG. 6 is a flow chart illustrating a process flow for fabricating solar cells, according to embodiment of the invention. At step 600 a burst of gas is flowed into the high vacuum load lock to elevate the pressure inside. At step 605 the valves separating the high pressure load locks from the transport stations are opened. At step 610 the system is energized to move one pitch, i.e., the conveyors inside the transport stations move one pitch, and the carriers with the chucks move one pitch—the carrier from the last processing chamber exiting to the unload elevator. At step 615 the load transport heads are energized to pick up wafers from the conveyor and loading them onto the chucks, while the unload transport heads are energized to remove wafers from the chucks positioned on the unload elevator and deliver them to the unload conveyor. At step 620 the system is energized to exchange carrier, meaning the unload elevator is lowered and the carrier is delivered to the chuck return module, a carrier that was previously stationed in the chuck return module is moved onto the load elevator and is raised to the load position. At step 625 the valves are closed, vacuum is pumped, and plasma processing commences. The cycle then repeats.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. A plasma processing system, comprising:
a loading station comprising a loading conveyor, a loading transport mechanism, and a chuck loading station accepting transportable electrostatic chucks, wherein the loading transport mechanism is configured to remove wafers from the conveyor and place them on the transportable electrostatic chucks;
at least one processing chamber coupled to the loading station and configured for receiving the transportable electrostatic chucks from the loading station and perform plasma processing of wafers positioned on the transportable electrostatic chucks;
an unloading station comprising an unloading conveyor, an unloading transport mechanism, and a chuck unloading station accepting the transportable electrostatic chucks from the processing chamber, wherein the unloading transport mechanism is configured to remove wafers from the transportable electrostatic chucks and place them on the conveyor; and,
a chuck return module configured for transporting the transportable electrostatic chucks from the chuck unloading station to the chuck loading station.

2. The system of claim 1, further comprising a chuck loading elevator position in the loading station and a chuck unloading elevator positioned in the unloading station.

3. The system of claim 2, wherein the loading conveyor, loading transport mechanism, chuck loading station, chuck loading elevator, unloading conveyor, unloading transport mechanism, chuck unloading elevator, and chuck unloading station are all maintained inside vacuum environment.

4. The system of claim 1, wherein the loading transport mechanism and the unloading transport mechanism each comprises electrostatic pickup chuck configured to chuck wafers from the front surface of the wafers.

5. The system of claim 4, wherein the electrostatic pickup chuck is movable between pickup position and drop position.

6. The system of claim 1, wherein the transportable chuck is mounted onto a carrier and wherein the carrier rides on rails provided in the loading station, processing chamber, unloading station, and chuck return module.

7. The system of claim 6, wherein the carrier comprises a plurality of permanent magnets, and wherein linear coils are positioned outside vacuum environment to apply magnetic motive force to the permanent magnets.

8. The system of claim 6, wherein the system comprises a plurality of carriers and a plurality of transportable chucks are mounted onto each carrier.

9. The system of claim 8, wherein the processing chamber is configured to accept one carrier at a time, to thereby simultaneously process a plurality of wafers positioned on the plurality of chucks mounted onto the one carrier.

10. The system of claim 1, wherein the chuck return module comprises a cooling station.

11. The system of claim 10, wherein the cooling station comprises a heat sink configured to remove heat by contacting the chucks.

12. The system of claim 1, wherein the loading conveyor and the unloading conveyor are energized intermittently to progress one pitch at a time.

13. The system of claim 1, wherein the processing chamber comprises a plasma shield confining the plasma over a plurality of wafers simultaneously.

14. The system of claim 13, wherein the chamber comprises a loading aperture and an unloading aperture that are permanently opened during loading, unloading and plasma processing.

15. The system of claim 1, further comprising a low vacuum loadlock receiving wafers from atmospheric environment, a high vacuum loadlock receiving wafers from the low vacuum loadlock, a valve positioned between the low vacuum loadlock and the high vacuum loadlock, and a conveyor traversing the low vacuum loadlock and the high vacuum loadlock, wherein the valve is configured to assume the shut position by pressing on the conveyor while the conveyor is stationary.

16. The system of claim 15, further comprising a loading valve positioned between the high vacuum loadlock and the loading station, and a controller configured to raise the pressure inside the high vacuum loadlock prior to opening the loading valve.

17. The system of claim 16, wherein the controller configured to raise the pressure inside the high vacuum loadlock by injecting a burst of gas into the high vacuum loadlock.

18. The system of claim 1, wherein the processing chamber comprises a contact configured for delivering chucking voltage to the transportable chuck.

19. A method for plasma processing of wafers, comprising:
delivering wafers into an evacuated loading station;
inside the evacuated loading station, loading the wafers onto transportable electrostatic chucks;
transporting the electrostatic chuck into a plasma processing chamber;
igniting and sustaining plasma inside the processing chambers to thereby process the wafers;
transporting the electrostatic chuck into an unloading station;
removing the wafers from the electrostatic chuck; and,
returning the chuck to the evacuated loading station.

20. The method of claim 19, wherein the step of loading the wafers onto transportable electrostatic chucks comprises electrostatically chucking wafers positioned on the conveyor and transporting the wafers onto the electrostatic chuck.
